(19) United States
(12) Patent Application Publication
(10) Pub. No.: US 2024/0201597 A1
(43) Pub. Date: Jun. 20, 2024

(54) DUV LITHOGRAPHY SYSTEM

(71) Applicant: Carl Zeiss SMT GmbH, Oberkochen (DE)

(72) Inventor: Stephan Six, Augsburg (DE)

(21) Appl. No.: 18/592,049

(22) Filed: Feb. 29, 2024

Related U.S. Application Data
(63) Continuation of application No. PCT/EP2022/070283, filed on Jul. 20, 2022.

(30) Foreign Application Priority Data
Sep. 16, 2021 (DE) 10 2021 210 243.3

(51) Int. Cl. G03F 7/20

(52) U.S. Cl. CPC G03F 7/2004; G03F 7/2008; G03F 7/201

(57) ABSTRACT

A DUV lithography apparatus comprises: a light source for generating DUV radiation at at least one operating wavelength in the DUV wavelength range; a photomask; and an optical element which transmits the DUV radiation and is spaced apart from the photomask and to which an absorbent coating is applied. The absorbent coating has absorbent microstructures which cover a surface region to which the absorbent coating is applied with a surface area proportion of less than 0.1% and optionally more than 0.01%.

### CROSS-REFERENCE TO RELATED APPLICATIONS

The present application is a continuation of, and claims benefit under 35 USC 120 to, international application No. PCT/EP2022/070283, filed Jul. 20, 2022, which claims benefit under 35 USC 119 of German Application No. 10 2021 210 243.3, filed Sep. 16, 2021. The entire disclosure of each these applications is incorporated by reference herein.

### FIELD

The disclosure relates to an optical arrangement for DUV lithography, such as a DUV lithography apparatus, comprising: a light source for generating DUV radiation at at least one operating wavelength in the DUV wavelength range; and an optical element which transmits the DUV radiation and to which an absorbent coating is applied.

### BACKGROUND

Within the meaning of this application, the DUV wavelength range is understood to be the wavelength range of electromagnetic radiation between 150 nm and 370 nm. The DUV wavelength range is relevant microlithography, for example. Radiation in the DUV wavelength range is thus used e.g. in projection exposure apparatuses and wafer or mask inspection apparatuses. There, both transmissive optical elements, e.g. in the form of lens elements or plane plates, and reflective optical elements, e.g. in the form of mirrors or the like, can be used, which are integrated for example in projection systems or illumination systems of DUV lithography apparatuses. In DUV lithography apparatuses, the light source is generally designed for generating DUV radiation having a single operating wavelength. In wafer or mask inspection apparatuses, the light source may be designed to generate broadband radiation at a plurality of operating wavelengths or in an operating wavelength spectrum.

US 20200409276 A1 describes a lithography apparatus having a temperature setting device with a first and a second temperature controller, each of which serves for setting a temperature distribution on an optical element of a projection system. The first and/or the second temperature controller are/is used to reduce changes in aberrations of the projection system during exposure operation or outside exposure operation. The two temperature controllers can have heating elements in the form of heating wires which are configured in arcuate fashion and which run along an outer edge region of a lens element. The heating elements can be arranged spaced apart from the optical element or can be in contact with the optical element.

U.S. Pat. No. 8,773,638 B2 describes a microlithographic projection exposure apparatus having a primary illumination system for generating projection light, a projection lens and an optical correction system with a secondary illumination system for generating correction light. The correction system can be configured, with the aid of the correction light, to heat partial regions of a correction element comprising a heating material in order to generate a locally varying optical path length and hence a local wavefront manipulation. The heating material of the correction element can be a coating of the correction element or the substrate of the correction element. All lens elements through which both the correction light and the projection light pass are produced from a lens element material which has a lower absorption coefficient for the correction light than the heating material contained in the correction element. The material of the lens element(s) should have a very low absorption coefficient both for a wavelength of the projection light (operating wavelength) and for a wavelength of the correction light that differs from the wavelength of the projection light, while the heating material of the correction element should have a low absorption coefficient for the wavelength of the projection light, but a high absorption coefficient for the wavelength of the correction light.

As described further above, in the case of using the correction element described in U.S. Pat. No. 8,773,638 B2, the heating material should have a high absorption coefficient for the wavelength of the correction light. In the case of a correction element whose main body is formed from synthetic quartz glass (SiO₂), the main body has a sufficient absorption only at wavelengths of the order of magnitude of approximately 2.6 μm or more. Many dielectric coating materials used for antireflection coatings at operating wavelengths in the DUV wavelength range of 193 nm, 248 nm or 365 nm, for example MgF₂, LaF₃, Al₂O₃, HfO₂ and TiO₂, also absorb radiation only at wavelengths above approximately 3 μm to approximately 10 μm.

U.S. Pat. No. 8,773,638 B2 describes an optical arrangement in which an optical element is impinged on by the radiation from a light source non-rotationally symmetrically. The optical element has an absorbent coating whose absorption is distributed in such a way that it is non-rotationally symmetrical at least approximately complementarily to the intensity distribution of the impingement of the radiation from the light source. The energy absorbed in the absorbent coating is intended to result in additional heating of the optical element that leads to a better rotationally symmetrical temperature distribution. In one example, the additional heating is realized by the absorption of projection light, a small proportion of which is absorbed in the coating. In a further example, the light source has a projection light source and a compensation light source, the radiation from the compensation light source being directed onto the absorbent coating. An absorption coefficient of the coating can be adapted to the emission wavelength of known light sources, e.g. of laser diodes. The extent of the additional heating can be set by way of the radiation power of the compensation light source.

In U.S. Pat. No. 8,773,638 B2, both during the absorption of projection light and during the absorption of radiation from the compensation light source, a central region of the optical element through which the projection light beam passes is not covered by the absorbent coating or is covered thereby only at its outer edge. It is therefore not possible to predefine or set the temperature distribution of the optical element in the surface region in which the projection beam is incident with high accuracy or spatial resolution.

### SUMMARY

The disclosure seeks to provide an optical arrangement in which a temperature distribution of the transmissive optical element can be predefined or set with high accuracy.

The disclosure provides an optical arrangement, wherein an absorbent coating has absorbent microstructures which cover a surface region to which the absorbent coating is applied with a surface area proportion of less than 0.1% and optionally of more than 0.01%.

The disclosure proposes applying a structured absorbent coating to the transmissive optical element. The structured absorbent coating comprises or consists of absorbent microstructures which cover only a small surface area proportion of the entire surface region to which the absorbent coating is applied. The surface area proportion of less than 0.1% does not involve a specific partial region of the surface region—covered with the absorbent coating—on which the microstructures are concentrated, rather the microstructures on the surface region are distributed over the entire surface region to which the absorbent coating is applied. By virtue of the small surface area proportion that is covered by the absorbent coating, the latter can also be applied within the surface region irradiated by the DUV radiation, without the DUV radiation being attenuated too much by the absorbent coating.

The microstructures are typically configured in locally delimited fashion in the manner of islands, a respective distance between two adjacent microstructures generally not being greater than 5 mm. The microstructures can be distributed for example in the manner of a grid, i.e. at equal distances from one another, on the surface region to which the absorbent coating is applied. This can help facilitate the setting of the temperature distribution when heating radiation is radiated onto the absorbent coating (see below). A uniform distribution of the microstructures in the surface region is not absolutely necessary, however. The absorbent microstructures absorb radiation in the DUV wavelength range, such as at the operating wavelength, and/or heating radiation at wavelengths of less than approximately 1550 nm (see below).

The structured absorbent coating can be formed on the surface region by a coating firstly being applied to the surface region over an extensive area, the coating comprising an absorbent material or consisting of an absorbent material. The structuring of the absorbent coating can be effected after the application of a structured protective resist, which is generally effected via a lithographic method, by way of a wet-chemical etching method or by way of dry etching in a reactive gas atmosphere. Alternatively, the material of the absorbent coating can be removed locally by laser ablation in order to form the absorbent microstructures. In this case, the laser beam can be focused to a beam spot on the absorbent coating applied over an extensive area, the dimension of the beam spot corresponding to the desired structure size of the microstructures. In this case, the laser beam is guided over the surface region and scans the latter with for example regular interruptions at those positions at which the absorbent microstructures are intended to be formed.

The transmissive optical element to which the absorbent coating is applied can be an optical element which contributes to the imaging, for example a lens element. However, the transmissive optical element can also be a correction element, e.g. in the form of a plane plate, which does not perform an optical function apart from the correction of wavefront aberrations.

In one embodiment, the surface region to which the absorbent coating is applied comprises or forms a surface region of the transmissive optical element that is irradiated by the DUV radiation. As has been described further above, the fact that the absorbent coating covers only a surface area proportion of less than 0.1% of the surface region to which the coating is applied makes it possible to apply the absorbent coating (also) in the surface region that is irradiated by the DUV radiation.

It is possible for the absorbent coating to be applied only in the irradiated surface region; however, it is also possible for the absorbent coating to encompass the irradiated surface region and additionally to extend to a non-irradiated surface region of the transmissive optical element that adjoins the irradiated surface region, in order in this way to adapt or set the temperature distribution at the edge of the irradiated surface region. In general, it is also possible for the absorbent coating to be applied only in a partial region of the irradiated surface region. In this case, however, the temperature distribution in the irradiated surface region can be set less precisely than for the case where the absorbent coating is applied to the entire irradiated surface region.

In an embodiment, the microstructures have a mean structure width of less than 20 μm, such as less than 10 μm. The mean structure width is defined as the arithmetic mean of the structure widths of all the microstructures of the absorbent coating. The structure width of a respective microstructure is understood to mean the maximum extent of the respective microstructure on the surface region, i.e. the longest straight line interconnecting two (arbitrary) points along the outer perimeter of the microstructure. The structure width of the microstructures can be predefined or set during the structuring of the absorbent coating. It is possible for all the microstructures to have a uniform structure width, but it is also possible for the structure widths of the microstructures to vary location-dependently. It can be desirable for the microstructures to have comparatively small structure widths, which can be smaller than the operating wavelength, in order to prevent the imaging properties of the optical arrangement from being disadvantageously influenced by the microstructures. Such disadvantageous influencing of the imaging properties may occur for example if the transmissive optical element is arranged in a projection optical unit of a DUV lithography apparatus that serves for imaging structures on a mask onto a wafer.

In an embodiment, the absorbent coating is configured as a metallic coating. On account of the comparatively small surface area proportion or the small coverage of the surface region with the absorbent microstructures, a high absorption and thus a high absorption coefficient of the absorbent coating in the DUV wavelength range can be used in order to generate a sufficient heating power. Metallic materials generally have a high absorption for radiation in the DUV wavelength range and thus in the range of the operating wavelength of the optical arrangement. Metallic materials moreover generally also absorb radiation in a wavelength range of less than approximately 1550 nm and are therefore also suitable for absorbing heating radiation that is radiated onto the absorbent coating at heating wavelengths that are outside the DUV wavelength range, for example at heating wavelengths in a wavelength range between approximately 370 nm or 400 nm and approximately 1550 nm.

In one development, the absorbent coating comprises at least one material selected from the group comprising: Cr, Al, Au and Ag. These metals have a high absorption coefficient for radiation in the DUV wavelength range. It goes without saying, however, that the absorbent coating can also comprise other metallic materials, particularly if the latter have a high absorption coefficient for radiation in the DUV wavelength range. In general, it is also possible for the absorbent coating to comprise nonmetallic materials if the latter have a sufficient absorption and are suitable for a structuring. The absorbent coating generally comprises just a single (e.g. metallic) layer, but can optionally also comprise two or more (e.g. metallic) layers.

In an embodiment, the absorbent coating (or the absorbent microstructures) has a thickness of between 50 nm and 200 nm. In order to introduce a maximum heating power into the absorbent coating despite the small surface area proportion of less than 0.1%, the absorbent coating, more precisely the absorbent microstructures, can be optically dense, i.e. transmit practically no radiation at the operating wavelength or at the heating wavelength (see below). The thickness used to produce an optically dense coating is dependent on the operating or heating wavelength and on the absorption coefficient of the absorbent, typically metallic, material of the coating. For the wavelengths and absorbent materials used here, the thickness of the absorbent coating or of the microstructures can be of the order of magnitude specified above.

In an embodiment, an antireflection coating for the DUV radiation at the operating wavelength is applied to the absorbent coating. The antireflection coating can comprise the surface region covered by the absorbent coating and also further regions of the surface of the transmissive optical element. The antireflection coating is generally applied both to a first, entrance-side, surface and to a second, exit-side, surface of the transmissive optical element. By contrast, the absorbent coating is typically applied only to the entrance-side surface of the transmissive optical element, but not to the exit-side surface of the transmissive optical element. In general, however, it is also possible for the absorbent coating to be applied on the exit-side surface of the transmissive optical element, or for an absorbent coating to be applied both on the entrance-side surface and on the exit-side surface.

In an embodiment, the surface area proportion of the microstructures varies location-dependently, for example depending on an intensity distribution of the DUV radiation in the surface region to which the absorbent coating is applied. In this embodiment, the absorption of the absorbent coating for the DUV radiation is typically predefined depending on the local intensity or the intensity distribution of the DUV radiation which is incident on the surface region. In this way, for a given or known intensity distribution, it is possible to predefine a predefined, static temperature distribution in the transmissive optical element and thus a predefined static wavefront or wavefront correction, without a heating radiation source being involved for this purpose.

The surface area proportion of the absorbent microstructures, for example, in partial regions of the surface region at which the local intensity of the DUV radiation is lower, can be chosen to be greater than in partial regions of the surface region at which the local intensity of the DUV radiation is higher. In this way, the additional absorption of the DUV radiation in the absorbent coating can help make it possible to predefine a temperature distribution that is as homogeneous as possible within the transmissive optical element and thus a wavefront that is as constant as possible upon passing through the transmissive optical element. However, it is also possible, by way of the location-dependent variation of the surface area proportion of the absorbent microstructures, to predefine in a targeted manner a desired wavefront that deviates from a plane or constant wavefront, for example in order to compensate for wavefront or imaging aberrations produced by other optical elements of the optical arrangement. The surface area proportion of the absorbent microstructures can be varied by the structure width of the microstructures varying location-dependently in the surface region and/or by the distance between adjacent microstructures varying location-dependently in the surface region.

In an embodiment, the transmissive optical element is arranged in or in the vicinity of a pupil plane. The arrangement in (or in the vicinity of) a pupil plane can be desirable, for example, in the case described further above where the local absorption or the surface area proportion of the microstructures varies depending on the intensity distribution of the incident DUV radiation. In this case, the local surface area proportion of the microstructures can be adapted to an illumination setting of an illumination system of the optical arrangement or can be optimized for an illumination setting which generates a specific intensity distribution of the DUV radiation on the optical element arranged in the pupil plane. Within the meaning of this application, the expression “in the vicinity of the pupil plane” is understood such that the transmissive optical element is arranged at a distance from the pupil plane at which an imaged image point illuminates a surface area proportion of at least 50% of the optical free surface or of the irradiated surface region of the transmissive optical element.

In one development, the optical arrangement additionally comprises a magazine with a plurality of transmissive optical elements each having a different location-dependent variation of the surface area proportion of the microstructures in the surface region to which the absorbent coating is applied, a transport device for transporting one of the transmissive optical elements from the magazine into a beam path of the optical arrangement and back, and also a control device for controlling the transport device, optionally depending on the illumination settings of the DUV lithography apparatus.

In this development, transmissive optical elements each having the absorbent coating with the absorbent microstructures as described further above are stored in the magazine. The transmissive optical elements differ in the location-dependent variation of the surface area proportion of the absorbent microstructures. The control device serves to select one of the transmissive optical elements which is suitable for the subsequent operation of the optical arrangement, and to introduce it into the beam path, or to exchange it for another, less well suited, transmissive optical element.

In this case, the location-dependent variation of the surface area proportion of the absorbent microstructures can for example be adapted to or optimized for one of a plurality of different illumination settings of an illumination system of a DUV lithography apparatus. In this case, the control device, depending on the illumination setting chosen, can select one of the transmissive optical elements which is optimized for this illumination setting. The illumination setting of the illumination system can be for example a dipole illumination, a quadrupole illumination, an annular field illumination, etc. The control device can be configured in the form of a suitable programmable device (hardware and/or software) having a processor and a memory.

In an embodiment, the optical arrangement comprises a heating device with at least one heating light source for radiating heating radiation onto the surface region of the transmissive optical element to which the absorbent coating is applied. As has been described further above, with the aid of the absorbent coating, radiant heating of the transmissive optical element can be realized even at heating wavelengths at which the material of the transmissive optical element and also the antireflection coating have no or only a very low absorption. In this case, the absorption of the heating radiation takes place in the structured absorbent coating that absorbs the heating wavelength(s).

In an embodiment, the heating light source is configured for radiating heating radiation onto the surface region at at least one heating wavelength which is in the wavelength range of between 400 nm and 1550 nm. As has been described further above, by virtue of the absorption of the heating radiation in the absorbent coating, it is possible to use heating light sources e.g. in the form of high-power diodes such as are used as standard in telecommunications applications in the wavelength range specified above.

In an embodiment, the heating device has a scanner device for aligning the heating radiation of a heating light source on different positions of the absorbent coating and/or a grid arrangement of heating light sources for irradiating different positions of the absorbent coating. The different positions on which the heating radiation is aligned can be for example the positions of the absorbent microstructures. With the aid of the scanner device, it is possible to scan for example the entire surface region covered by the absorbent coating, the power or the intensity of the heating light source, for example of a laser, being varied location-dependently in order to generate a desired intensity distribution in the surface region covered by the absorbent coating. In this case, optionally, at positions on the surface region which are situated between the absorbent microstructures, the power of the heating light source can be reduced practically almost to zero. For the case where a plurality of heating light sources, e.g. in the form of (laser) diodes, are arranged in an array, a respective heating light source is typically assigned to a position on the surface region on which at least one absorbent microstructure is situated. For example, in this embodiment it can be desirable for the absorbent microstructures in the surface region to likewise arranged in a grid. Moreover, in this case it is generally desirable for all the absorbent microstructures to have the same structure width, i.e. for the surface area proportion to not vary location-dependently.

The concept described further above for the local radiant heating of a transmissive optical element with the aid of a structured absorbent coating can also be combined with other concepts which make it possible to predefine or set a temperature distribution, for example resistance heating, e.g. using heating elements in the form of heating wires, as is described for example in U.S. 20200409276 A1, cited in the introduction.

Further features of the disclosure are evident from the following description of exemplary embodiments of the disclosure, with reference to the figures of the drawing, which show certain details of the disclosure, and from the claims. The individual features can each be realized individually by themselves or as a plurality in any desired combination in a variant of the disclosure.

### BRIEF DESCRIPTION OF THE DRAWINGS

Exemplary embodiments are illustrated in the schematic drawing and are explained in the following description. In the figures:

FIG. 1 shows a schematic illustration of a DUV lithography apparatus,

FIG. 2A shows a schematic illustration of a transmissive optical element having an absorbent coating with a plurality of absorbent microstructures with location-dependently varying structure widths, and

FIG. 2B shows a schematic illustration analogous to FIG. 2B, in which heating radiation with a location-dependently varying intensity is radiated onto the absorbent microstructures.

### DETAILED DESCRIPTION

In the following description of the drawings, identical reference signs are used for identical or functionally identical components.

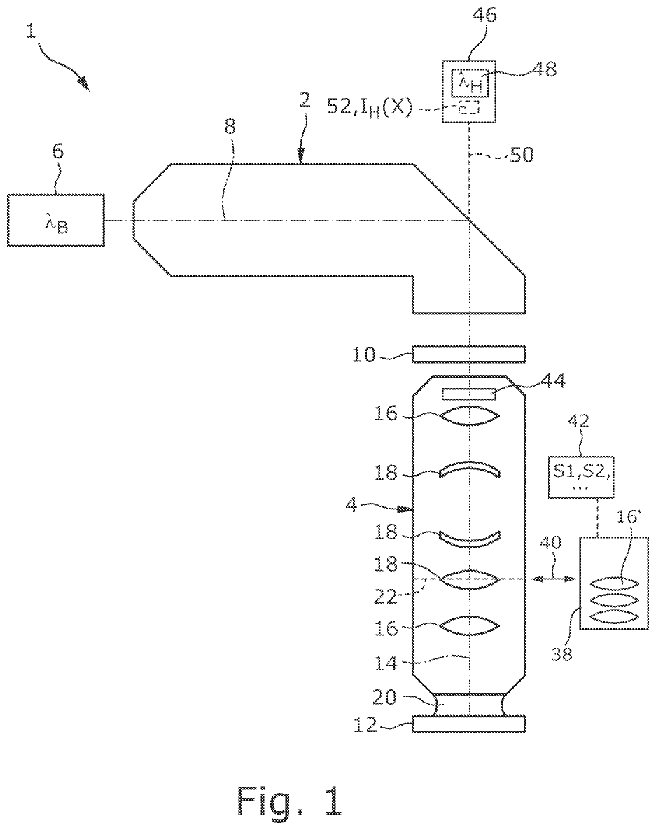

FIG. 1 shows a schematic view of a DUV lithography apparatus 1 comprising a beam shaping and illumination system 2 and a projection system 4. The beam shaping and illumination system 2 and the projection system 4 can be arranged in a vacuum housing and/or be surrounded by a machine room with corresponding drive devices.

The DUV lithography apparatus 1 comprises a DUV light source 6. For example, an ArF excimer laser that emits DUV radiation 8 in the DUV wavelength range for example at an operating wavelength λ_{B} of 193 nm can be provided as the DUV light source 6. Alternatively, a DUV light source 6 that emits DUV radiation 8 at a different operating wavelength λ_{B} in the DUV wavelength range, for example at 248 nm or at 365 nm, can be used.

The beam shaping and illumination system 2 illustrated in FIG. 1 guides the DUV radiation 8 onto a photomask 10. The photomask 10 is configured as a transmissive optical element and can be arranged outside the systems 2, 4. The photomask 10 comprises a structure which is imaged onto a wafer 12 or the like in reduced form via the projection system 4.

The projection system 4 comprises a plurality of lens elements 16 and/or mirrors 18 for imaging the photomask 10 onto the wafer 12. In this case, individual lens elements 16 and/or mirrors 18 of the projection system 4 can be arranged symmetrically with respect to the optical axis 14 of the projection system 4. It should be noted that the number of lens elements and mirrors of the DUV lithography apparatus 1 is not restricted to the number illustrated. More or fewer lens elements and/or mirrors can also be provided. Furthermore, the mirrors are generally curved on their front side for beam shaping.

An air gap between the last lens element 16 and the wafer 12 can be replaced by a liquid medium 20 having a refractive index >1. The liquid medium can be high-purity water, for example. Such a set-up is also referred to as immersion lithography and has an increased resolution during the imaging of the photomask 10 onto the wafer 12.

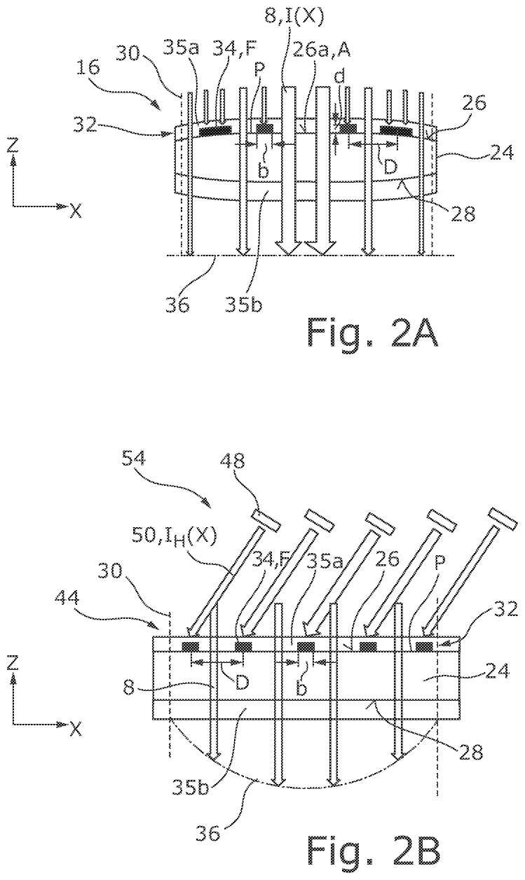

One of the transmissive lens elements 16 of the projection system 4, which is arranged in a pupil plane 22 of the projection system 4, is illustrated in detail in FIG. 2A. The lens element 16 comprises a main body 24 comprising or consisting of synthetic quartz glass (SiO₂) in the example shown, the quartz glass being transparent to the DUV radiation 8. The main body 24, on its two opposite sides, has a first, entrance-side surface 26 and a second, exit-side surface 28, through which the DUV radiation 8 passes. A beam path 30 of the DUV radiation 8, more precisely the outer edge of the beam path, is illustrated in a dashed manner in FIG. 2A. As can be discerned in FIG. 2A, the DUV radiation 8 is radiated onto the first surface 26 of the lens element 16 in a surface region 26a which does not cover the entire first surface 26 of the lens element 16, i.e. an outer partial region of the first surface 26 is not impinged on by the DUV radiation 8.

As can likewise be discerned in FIG. 2A, a structured absorbent coating 32 is applied to the surface region 26a which is irradiated by the DUV radiation 8. In the example shown in FIG. 2A, the structured absorbent coating 32 comprises or consists of a plurality of absorbent microstructures 34, illustrated as black rectangles in FIG. 2A. The absorbent microstructures 34 do not completely cover the surface region 26a to which the absorbent coating 32 is applied, but rather cover the surface region only with a surface area proportion F that is between 0.01% and 0.1% of the total area A of the irradiated surface region 26a. On account of the small surface area proportion F of the structured absorbent coating 32, it is ensured that only a small proportion of the DUV radiation 8 is absorbed by the absorbent microstructures 34 and the transmission of the optical element 16 decreases only slightly as a result of the absorbent coating 34.

In the example shown in FIG. 2A, the structured absorbent coating 32, more precisely the absorbent microstructures 34, is optically dense for the DUV radiation 8 at the operating wavelength λ_{B}, i.e. these transmit practically no DUV radiation 8. In order to achieve this, it is desirable for the absorbent microstructures 34 or the absorbent coating 32 to have a sufficient thickness d, which can typically be of an order of magnitude of between 50 nm and 200 nm. In addition, the absorbent microstructures 34 can comprise a material having the largest possible absorption coefficient for the DUV radiation 8.

In the example shown in FIG. 2A, the absorbent coating 32 is configured as a metallic coating, i.e. the absorbent microstructures 34 comprise or consist of a metallic material. This can be desirable since metallic materials generally have a high absorption coefficient in the DUV wavelength range between approximately 150 nm and approximately 370 nm. In the example shown, the metal which the absorbent microstructures 34 comprise or consist of is Cr, but it may also be a different metal having a high absorption coefficient, for example Al, Au or Ag. As is likewise illustrated in FIG. 2A, an antireflection coating 35a for the DUV radiation 8 is applied to an extensive area of the absorbent coating 32 on the first surface 26. An antireflection coating 35b for the DUV radiation 8 is likewise applied on the second surface 28. The antireflection coatings 35a,b are coatings composed of fluoridic or oxidic materials, for example composed of MgF₂, LaF₃, Al₂O₃, HfO₂ or TiO₂, which have a comparatively low absorption for the DUV radiation 8.

The absorbent microstructures 34 are formed by an absorbent coating composed of a metal, in the example described here composed of chromium, firstly being deposited on the surface region 26a over an extensive area. A conventional coating method is used for the deposition. In the example shown, for the structuring of the absorbent coating 32, a structured protective resist was applied to the metallic coating, the resist serving as an etching mask for a subsequent etching method in which the metallic coating is removed in the regions not covered by the protective resist, with the result that only the absorbent microstructures 34 remain on the surface region 26a. The etching method can be a wet-chemical etching method, but dry etching in a reactive gas atmosphere is also possible. Alternatively, the absorbent microstructures 34 can also be produced by laser ablation on a metallic coating or layer applied over an extensive area.

In order not to adversely affect the quality of the imaging of the structure of the photomask 10 onto the wafer 12, the absorbent microstructures 34 should not have excessively large structure widths b. In the example shown in FIG. 2B, the structure width b of the absorbent microstructures 34 varies location-dependently, but the structure width b averaged over all the microstructures 34 is less than 20 μm, more precisely less than 10 μm. In FIG. 2A, the absorbent microstructures 34 are not arranged with exactly uniform distribution, i.e. the distances D between the centers of adjacent absorbent microstructures 34 are not constant, rather these vary location-dependently. In the example shown in FIG. 2A, the surface area proportion F of the absorbent microstructures 32 therefore varies location-dependently, i.e. depending on a position P on the irradiated surface region 26a.

The variation of the surface area proportion F of the absorbent microstructures 34 along the irradiated surface region 26a depends on the variation of the intensity distribution I(x) of the DUV radiation 8 along the irradiated surface region 26a in the X-direction. It goes without saying that the intensity distribution of the DUV radiation 8 varies in the Y-direction, too, although this cannot be discerned in the sectional illustration of the lens element 16 in FIG. 2A. In the example shown in FIG. 2A, the location-dependently variable power density or intensity distribution I(x) of the DUV radiation 8 incident on the surface region 26a is symbolized by arrows of different widths, where wider arrows correspond to a higher power density or local intensity I(x) and narrower arrows correspond to a lower power density or local intensity I(x).

As can be discerned in FIG. 2A, the surface area proportion F of the absorbent microstructures 34, at less intensely irradiated positions P at which the local intensity I(x) of the DUV radiation 8 is lower, is greater than at positions P at which the local intensity I(x) of the DUV radiation 8 is higher. The greater heating of the main body 24 at positions P with higher intensity I(x) of the DUV radiation 8 is compensated for in this case by virtue of the surface area proportion F of the absorbent microstructures 34 being greater at positions P with lower intensity I(x) of the DUV radiation 8, such that there more DUV radiation 8 is absorbed in the coating 32. A homogeneous temperature distribution and thus a homogeneous refractive index in the main body 24 can be generated in this way. As the DUV radiation 8 passes through the lens element 16, a plane wavefront 36, indicated in a dash-dotted manner in FIG. 2A, can be generated or obtained in this way. It goes without saying that a wavefront 36 with a fundamentally arbitrary geometry can be generated by way of a suitably adapted location-dependent variation of the surface area proportion F of the absorbent microstructures 34 on the lens element 16.

It goes without saying that the desired wavefront 36 is generated only for a specific intensity distribution I(x) of the incident DUV radiation 8. For the case where the intensity distribution I(x) varies, for example because the illumination settings of the beam shaping and illumination system 2 vary, a wavefront 36 is generated whose geometry deviates from the desired geometry.

In order that the desired temperature distribution in the main body of the lens element 16 and thus a target wavefront 36 are generated in this case, too, the DUV lithography apparatus 1 illustrated in FIG. 1 comprises a magazine 38, in which are stored a plurality of transmissive optical elements 16′ each having a different location-dependent variation of the surface area proportion F of the microstructures 34 in the surface region 26a to which the absorbent coating 32 is applied. In this case, a respective transmissive optical element 16′, more precisely the variation of the surface area proportion F, is optimized for each of a plurality of illumination settings S1, S2, . . . of the beam shaping and illumination system 2. For the purpose of exchanging the lens element 16 arranged in the beam path 30 for one of the lens elements 16′ stored in the magazine 38, the DUV lithography apparatus 1 comprises a transport device 40, which can be for example a lever arm or the like. For the control of the transport device 40, the DUV lithography apparatus 1 comprises a control device 42. The control device 42 is configured, in the event of a change in the illumination setting S1, S2, . . . of the projection and illumination system 2, to exchange the lens element 16 arranged in the beam path 30 for that one of the lens elements 16′ stored in the magazine 38 whose location-dependent variation of the surface area proportion F is optimized for the respective illumination setting S1, S2, . . . .

In the case of the lens element 16 described in FIG. 2A, the desired temperature distribution in the main body 24 and thus the desired wavefront 36 are generated by way of the location-dependent variation of the surface area proportion F of the absorbent microstructures 34. The transmissive optical element 44 illustrated in FIG. 2B differs from the optical element 16 illustrated in FIG. 2A firstly in that it is a plate-type optical element (a plane-parallel plate). In addition, the absorbent microstructures 34 in the case of the plate-type optical element 44 shown in FIG. 2B are arranged in a grid at equal distances D from one another and have identical structure widths b. In the case of the optical element 44 illustrated in FIG. 2B, therefore, the surface area proportion F of the absorbent microstructures 34 does not vary location-dependently, but rather is constant.

In order to generate a desired temperature distribution in the main body 24 of the optical element 44 in the example shown in FIG. 2B, a heating device 46 is used, which serves for the radiant heating of the optical element 44 (cf. FIG. 1). In the example shown in FIG. 1, the heating device 46 has a heating light source 48 comprising a laser, for example in the form of a high-power laser diode, which generates heating radiation 50 at a heating wavelength λ_{H}. The heating device 46 also comprises a scanner device 52 comprising one or more scanner mirrors for deflecting the heating radiation 50 that is coupled into the beam path 30 of the projection system 4. The heating radiation 50 impinges on the plate-type optical element 44, which is the first optical element in the beam path 30 of the projection system 4. With the aid of the scanner device 52, it is possible to alter a position P of the heating radiation 50 on the plate-type optical element 44. The power of the heating light source 48 is adjustable, and so it is possible to generate a location-dependent intensity distribution I_{H}(x) of the heating radiation 50 on the first surface 26 of the plate-type optical element 44. In the example shown in FIG. 2B, the surface region onto which the heating radiation 50 is radiated and to which the absorbent coating 32 is applied is the entire first surface 26 of the plate-type optical element 44, encompassing the surface region 26a irradiated by the DUV radiation 8. The control device 42 can serve to control the heating light source 48 in order to predefine a location-dependent intensity distribution I_{H}(x) adapted to the respective illumination setting S1, S2, . . . of the beam shaping and illumination system 2 at the surface 25 of the plate-type optical element 26.

As an alternative or in addition to the heating light source 48 illustrated in FIG. 1, the heating device 46 can have a grid arrangement 54 of heating light sources 48, e.g. in the form of laser diodes, as is illustrated in FIG. 2B. The power of the heating radiation 50 that is generated by a respective heating light source 48 can be set individually, as is indicated by arrows of different widths in FIG. 2B. In the example shown in FIG. 2B, a respective heating light source 48 is aligned with a respective one of the absorbent microstructures 34. It goes without saying, however, that in general a respective heating light source 48 is aligned with a plurality of the absorbent microstructures 34. By virtue of the individual setting of the power of the heating light sources 48, it is likewise possible to generate or set a location-dependent intensity distribution I_{H}(x) of the heating radiation 50 at the first surface 26.

The possibility of actively influencing the intensity distribution I_{H}(x) of the heating radiation 50 enables the generation of a desired temperature distribution in the main body 24 of the plate-type optical element 44, the distribution generating a wavefront 36 with a desired geometry. In this way, an active setting or correction of the wavefront 36 of the projection system 4 of the DUV lithography apparatus 1 can be performed with the aid of the optical element 44 shown in FIG. 2B. In this case, in particular wavefront aberrations generated at other optical elements 16, 18 of the projection system 4 can be compensated for.

Both the heating light source 48 shown in FIG. 1 and the heating light sources 48 of the grid arrangement 52 of FIG. 2B are configured to radiate the heating radiation 50 onto the plate-type optical element 44 at a heating wavelength λ_{H} that is in a wavelength range of between 400 nm and 1550 nm. This is possible because the absorbent coating 32 also absorbs radiation in the specified wavelength range. Therefore, conventional high-power diodes such as are customary for telecommunications applications can be used as heating light source(s) 48.

What is claimed is:

1. An optical arrangement, comprising:
a light source configured to generate radiation at an operating wavelength in the DUV wavelength range;
an optical element configured to transmit radiation at the operating wavelength; and
a heating device comprising a heating source configured to radiate heating radiation,
wherein:
the optical element comprises a surface region;
an absorbent coating is disposed on the surface region;
the absorbent coating comprises absorbent microstructures;
the absorbent microstructures cover less than 0.1% of the surface region; and
the heating light device is configured to radiate the heating radiation onto the surface region.

2. The optical arrangement of claim 1, wherein the absorbent microstructures cover more than 0.01% of the surface region.

3. The optical arrangement of claim 1, wherein the optical arrangement is configured so that the radiation at the operating wavelength irradiates the surface region during use of the optical arrangement.

4. The optical arrangement of claim 1, wherein the absorbent microstructures have a mean structure width of less than 20 micrometers.

5. The optical arrangement of claim 1, wherein the absorbent coating comprises a metallic coating.

6. The optical arrangement of claim 1, wherein the absorbent coating comprises at least one member selected from the group consisting of chromium, aluminum, gold and silver.

7. The optical arrangement of claim 1, wherein the absorbent coating has a thickness of between 50 nm and 200 nm.

8. The optical arrangement of claim 1, further comprising an antireflection coating disposed on the absorbent coating, wherein the antireflection coating is antireflective for the radiation at the operating wavelength.

9. The optical arrangement of claim 1, wherein distances between adjacent absorbent microstructures are not constant.

10. The optical arrangement of claim 1, wherein distances between adjacent absorbent microstructures vary depending on an intensity distribution of radiation at the operating wavelength in the surface region during use of the optical arrangement.

11. The optical arrangement of claim 1, wherein the optical element is in a pupil plane or in a vicinity of a pupil plane.

12. The optical arrangement of claim 1, further comprising:
a magazine comprising a plurality of transmissive optical elements;
a transport device configured to transport a transmissive optical element from the magazine into a beam path of the optical arrangement; and
a control device configured to control the transport device,
wherein different transmissive optical elements have different distances between adjacent absorbent microstructures.

13. The optical arrangement of claim 1, wherein the optical element comprises an imaging optical element.

14. The optical arrangement of claim 1, wherein the optical element comprises a lens element.

15. The optical arrangement of claim 1, wherein the optical element comprises a plate-type element configured to correct wavefront aberrations.

16. The optical arrangement of claim 1, wherein the heating radiation is in a wavelength range of between 400 nm and 1550 nm.

17. The optical arrangement of claim 1, wherein the heating device (46) is configured to radiate the heating radiation onto the surface region with a location-dependently variable intensity distribution.

18. The optical arrangement of claim 1, wherein the heating device comprises a scanner device configured to align the heating radiation on different positions.

19. The optical arrangement of claim 1, wherein the heating device comprises a grid arrangement of heating light sources configured to irradiate different positions of the absorbent coating with the heating radiation.

20. A lithography apparatus, comprising:
an illumination system; and
a projection system comprising the optical arrangement of claim 1.
